(19) United States
(12) Patent Application Publication
(10) Pub. No.: US 2006/0159843 A1
(43) Pub. Date: Jul. 20, 2006

(54) Method of substrate treatment for manufacturing of color filters by inkjet printing systems

(75) Inventors: Fan-Cheung Sze, San Jose, CA (US); Quanyuan Shang, Saratoga, CA (US); John M. White, Hayward, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/039,603

(22) Filed: Jan. 18, 2005

(51) Int. Cl. B05D 5/12; B05D 5/06; C23C 16/00

(52) U.S. Cl. 427/68; 427/64; 118/726

(57) ABSTRACT

A method for treating a glass substrate and a black matrix thereon for a flat panel display is provided. In one application, the treatment of the glass substrate and black matrix is performed prior to delivery of ink to the glass substrate by an inkjet printing system. The black matrix and glass substrate are exposed to a surface active compound. In one aspect, exposing the black matrix and the glass substrate to a surface active compound modifies the surface energy of the black matrix, the surface energy of the glass substrate, or both. In another aspect, treating the black matrix and the glass substrate enhances the formation of color filters having sub-pixel wells that have a substantially uniform distribution of ink therein.

### BACKGROUND OF THE INVENTION

1. Field of the Invention

Embodiments of the invention generally relate to flat panel displays and particularly relate to methods of treating a black matrix and a substrate for use in flat panel displays.

2. Description of the Related Art

Flat panel displays (FPDs) have become the favored display technology for computers, televisions, and personal electronic devices such as cell phones, personal digital assistants, etc. Liquid crystal displays (LCDs) are a preferred type of commercially available FPDs. Different colors are obtained in liquid crystal displays by transmitting light through a color filter located on a substrate of a LCD. The color filter includes pixels, wherein each pixel may include three colors, typically red, green, and blue. Each color of a pixel may be considered a sub-pixel. Typically, each sub-pixel is surrounded by a black matrix material that provides an opaque area between sub-pixels and therefore prevents light leakage in the thin film transistors (TFTs) of the LCD. FIG. 1 is a top view of two adjacent pixels 1 and 2. Pixel 1 includes three sub-pixels 3, 4, and 5, and pixel 2 includes three sub-pixels 6, 7, and 8. Black matrix material 9 surrounds and separates each of the sub-pixels 3, 4, 5, 6, 7, and 8.

Traditional methods of producing color filters, such as dyeing, lithography, and electrodeposition, require the sequential introduction of the three colors. That is, a first set of pixels having one color is produced by a series of steps, whereupon the process must be repeated twice more to apply all three colors. The series of steps involved in this process includes at least one curing phase in which the deposited liquid color agent must be transformed into a solid, permanent form. Thus, such traditional methods of producing color filters can be very time consuming. Also, as each color agent is processed by a separate line of equipment, equipment costs for such traditional methods are high.

Methods of using inkjet systems that allow the deposition of all three colors simultaneously have been developed. An inkjet system may be used to deposit different colors through different nozzles into wells created by a patterned black matrix on a substrate, wherein each well corresponds to a sub-pixel. However, the formation of color filters remains challenging. For example, as the size of pixels and sub-pixels decreases, the precision of the delivery of the ink into the sub-pixel wells created by the patterned black matrix must be increased. Furthermore, the surface properties of the glass and the black matrix are becoming increasingly important, as it is desired that the ink be able to spread and uniformly fill a small well within the black matrix and yet not spread across and over the black matrix into a neighboring well. A non-uniformly, filled sub-pixel well, i.e., a well having an irregular ink upper surface profile, is undesirable, as it will typically not provide a uniform color.

Therefore, a need exists for an improved method for forming color filters for flat panel displays. In particular, there is a need for a method of providing a patterned black matrix that enhances the formation of color filters having sub-pixel wells that have a uniform distribution of ink within each well.

### SUMMARY OF THE INVENTION

The present invention provides a method of treating a glass substrate and a black matrix for a flat panel display. In one embodiment, the method comprises exposing the glass substrate and the black matrix to a surface active compound under conditions sufficient to modify the surface energy of the black matrix, an outer surface of the glass substrate that is not covered by the black matrix, or both. Modifying the surface energy may include increasing or decreasing the ink-philicity or ink-phobicity of an outer surface of the black matrix or of the outer surface of the glass substrate. The difference between the modified surface energy of the black matrix or glass substrate and the surface energy of the ink to be delivered to the sub-pixel wells of the black matrix may be between about 4 dynes/cm and about 12 dynes/cm. The surface active compound may be a silane-based organic compound, fluorinated hydrocarbon, long chain hydrocarbon-based acid, long chain hydrocarbon-based ester, long chain hydrocarbon-based phosphate, long chain hydrocarbon-based sulfate, or a combination thereof.

Embodiments of the invention include exposing the glass substrate and the black matrix to the surface active compound by immersing the glass substrate in or spraying the glass substrate with a solution of the surface active compound dissolved in one or more solvents, and then removing the one or more solvents to form a thin layer of the surface active compound on the glass substrate and black matrix. Further embodiments of the invention include vaporizing the surface active compound before exposing the glass substrate and the black matrix to the surface active compound.

Further aspects of the invention include depositing ink in the sub-pixel wells of the black matrix after the black matrix is exposed to a surface active compound under conditions sufficient to modify the surface energy of the black matrix. The glass substrate may be dried before the ink is deposited and after the black matrix is exposed to the surface active compound.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a top view of two pixels each containing three sub-pixels according to the prior art.

FIG. 2 is a cross-section of a sub-pixel well surrounded by a black matrix material according to the prior art.

FIG. 3 is a cross-section of a sub-pixel well surrounded by a black matrix material according to the prior art.

FIG. 4 is a top view of two sub-pixels according to the prior art.

FIG. 5 is a cross-section of a sub-pixel well surrounded by a black matrix material according to embodiments of the invention.

FIG. 6 is a schematic view of an apparatus comprising a bubbler-type vaporizer and a heated applicator according to embodiments of the invention.

FIG. 7 is a schematic view of another apparatus comprising a vaporizer and a heated applicator according to embodiments of the invention.

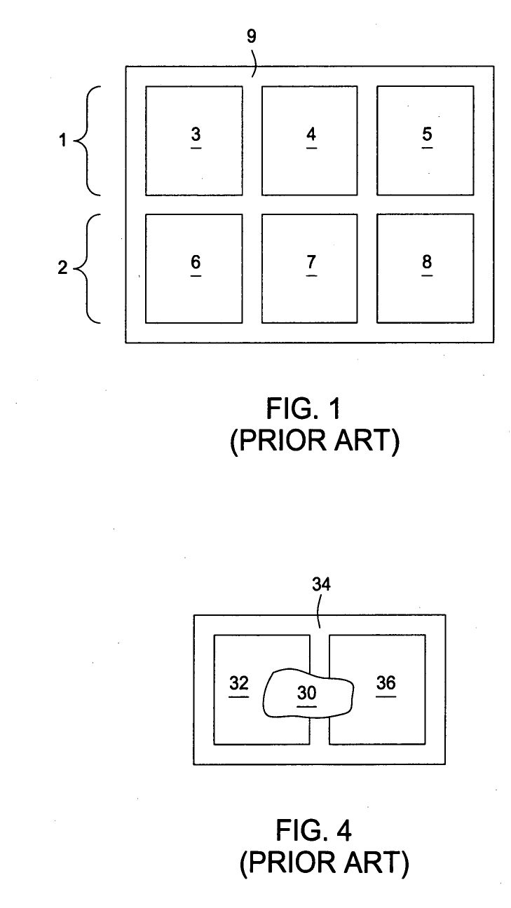

### DETAILED DESCRIPTION

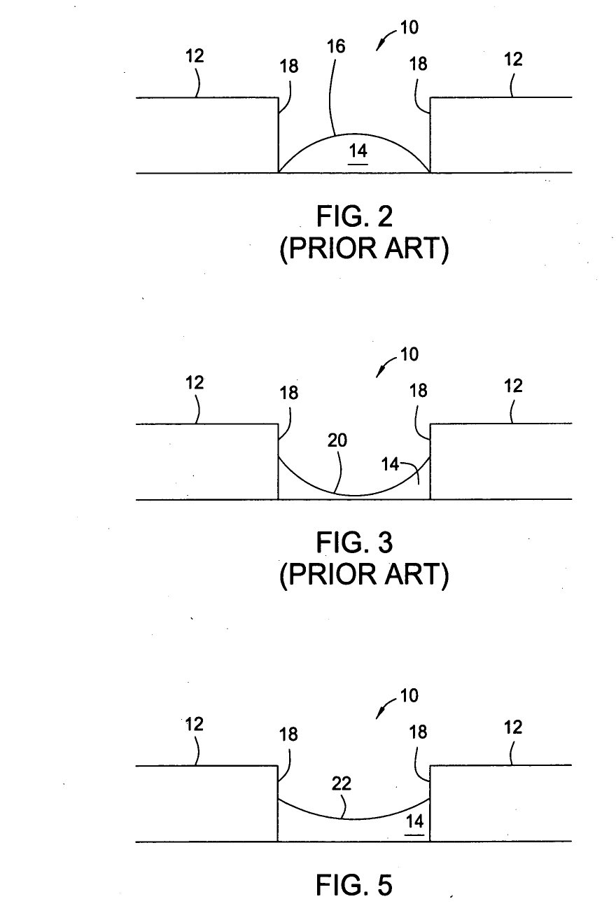

Convex ink upper surface profiles and concave ink upper surface profiles are two examples of irregular ink upper surface profiles that may result, at least in part, from an ink contacting a black matrix having undesirable surface properties. A convex ink upper surface profile may be caused by a black matrix having surface properties that repel the ink away from the black matrix and towards the center of the sub-pixel well. An example of a cross-section of a sub-pixel well surrounded by a black matrix having surface properties that result in a convex ink upper surface profile is shown in FIG. 2. A sub-pixel well 10 is surrounded by a black matrix 12. The black matrix 12 has surface properties such that ink 14 deposited in the sub-pixel well 10 is repelled by the sidewalls 18 of the sub-pixel well 10, resulting in a convex, dome-shaped upper surface profile 16 of the, ink 14 within the sub-pixel well 10 rather than a uniform upper surface profile.

A concave ink upper surface profile may be caused by a black matrix having surface properties that attract the ink away from the center of the sub-pixel well and towards the black matrix. An example of a cross-section of a sub-pixel well surrounded by a black matrix having surface properties that result in a concave ink upper surface profile is shown in FIG. 3. The ink 14 in the sub-pixel well 10 of FIG. 3 has a concave upper surface profile 20, as the sidewalls 18 comprising the black matrix 12 of the sub-pixel well 10 attract the ink such that the ink is raised by the attraction force along the sidewalls and away from the center of the sub-pixel well.

The outer surface of the glass substrate that is not covered by the black matrix, i.e., the surface of the glass substrate that contacts the ink in the sub-pixel wells, may also have undesirable surface properties. For example, a glass substrate outer surface that has a high affinity for an ink may result in the spreading of the ink deposited in one sub-pixel well to another sub-pixel well. FIG. 4 shows an example of a drop of ink 30 that was deposited in sub-pixel well 32 and then spread over the black matrix 34 into adjacent sub-pixel well 36.

Embodiments of the invention provide a method of treating a glass substrate and a black matrix thereon that enhances the formation of color filters having sub-pixel wells that have a substantially uniform distribution of ink therein. The glass substrate and black matrix are treated under conditions sufficient to modify the surface energy of at least one member selected from the group consisting of the black matrix and an outer surface of the glass substrate that is not covered by the black matrix, such that ink deposited in the sub-pixel wells has a substantially uniform upper surface profile. As defined herein, a sub-pixel well having an ink thickness variation across the sub-pixel well of up to about +/−15% is a sub-pixel well having a substantially uniform upper surface profile. The ideal ink surface thickness uniformity is +/−3%. A sub-pixel well having an ink thickness variation across the sub-pixel well of up to about +/−15% and a surface profile that is substantially uniform in the middle of a sub-pixel well and slightly concave at the edges of the sub-pixel well is an example of a sub-pixel well having a substantially uniform upper surface profile. The resulting black matrix and glass substrate surface energy are such that the ink spread is sufficiently flat inside the sub-pixel wells and little ink is spread on the black matrix surface and into adjacent wells. A slightly convex or concave ink upper surface profile will not affect the color quality of the display. A slightly concave ink upper surface profile is preferred.

An example of a cross-section of a sub-pixel well surrounded by a black matrix treated according to embodiments herein is shown in FIG. 5. The ink 14 in the sub-pixel well 10 of FIG. 5 has a substantially uniform upper surface profile 22 as it is not strongly repelled or attracted by the sidewalls 18 of the sub-pixel well 10.

As defined herein, a material such as a glass substrate or a black matrix that has an outer surface such that an ink deposited thereon tends to spread is ink-philic, and a material such as a glass substrate or a black matrix that has an outer surface such that an ink deposited thereon does not tend to spread is ink-phobic. Furthermore, as used herein, increasing the attractive force between a material, such as a glass substrate or a black matrix, and an ink deposited thereon such that the tendency of the ink to spread on the material is increased is referred to as either increasing the ink-philicity of the material or decreasing the ink-phobicity of the material. Decreasing the attractive force between a material, such as a glass substrate or a black matrix, and an ink deposited thereon such that the tendency of the ink to spread on the material is decreased is referred to as either increasing the ink-phobicity of the material or decreasing the ink-philicity of the material.

In one embodiment, modifying the surface energy of an outer surface of the glass substrate that is not covered by the black matrix comprises increasing the ink-phobicity of the outer surface of a glass substrate that when untreated has a high affinity for an ink to be deposited in the sub-pixel wells defined by the black matrix and thus typically results in ink spreading over the black matrix, as shown in FIG. 4. Increasing the ink-phobicity of the outer surface of such a glass substrate reduces the tendency of the deposited ink to flow towards the sidewalls and over the black matrix.

In another embodiment, modifying the surface energy of the black matrix comprises increasing the ink-phobicity of the outer surface of a black matrix that when untreated has a high affinity for an ink to be deposited in the sub-pixel wells defined by the black matrix and thus typically results in a concave ink upper surface profile as shown in FIG. 3. As defined herein, the outer surface of a black matrix consists of the surfaces of the black matrix that do not contact the glass substrate. Increasing the ink-phobicity of the outer surface of such a black matrix reduces the tendency of the deposited ink to flow preferentially to the sidewalls and away from the center of the sub-pixel well.

In a further embodiment, modifying the surface energy of an outer surface of the glass substrate that is not covered by the black matrix comprises decreasing the ink-phobicity of the outer surface of a glass substrate that when untreated has a low affinity for an ink to be deposited in the sub-pixel wells defined by the black matrix and thus typically results in a convex ink upper surface profile as shown in FIG. 2. Decreasing the ink-phobicity of the outer surface of such a glass substrate reduces the tendency of the deposited ink to form a dome-shaped bead of ink within the center of the sub-pixel well.

In another embodiment, modifying the surface energy of the black matrix comprises decreasing the ink-phobicity of the outer surface of a black matrix material that when untreated has a low affinity for an ink to be deposited in the sub-pixel wells defined by the black matrix and thus typically results in a convex ink upper surface profile as shown in FIG. 2. Reducing the ink-phobicity of the outer surface of such a black matrix material reduces the tendency of the deposited ink to flow preferentially away from the sidewalls of the sub-pixel well.

In any of the embodiments of the invention, the glass substrate and the black matrix are exposed to a surface active compound to modify the surface energy of the glass substrate, the surface energy of the black matrix, or the surface energies of both. In one aspect, the surface active compound may be any compound or mixture of compounds that adheres both to a glass substrate and a black matrix and that does not substantially react with or change the properties of an ink deposited thereon. For example, the surface active compound may form a layer when deposited on the glass substrate and black matrix such that the layer comprises a first side adapted to provide an ink-phobic surface or an ink-philic surface and a second side opposite the first side and adapted to adhere to the glass substrate and black matrix. The layer has a thickness sufficient to modify the surface energy of the glass substrate, black matrix, or both while not depositing a substantial amount of material in the sub-pixel well. For example, the layer may have a thickness of about a submonolayer, e.g., about 5 Å, to about 100 Å. The layer may consist of one or several monolayers of the surface active compound. In one embodiment, the surface active compound includes a silicon component that adheres to the glass and a hydrocarbon component that provides an ink-phobic surface. An example of such a surface active compound is a silane-based organic compound, such as a silicone oil. Other surface active compounds that may be used include fluorinated hydrocarbons, such as fluoroalkyl polyoxyethylene polymers, long chain hydrocarbon-based acids, such as oleic acid, long chain hydrocarbon-based esters, such as esters having the general structure of R₁COOR₂, where R₁ and R₂ are hydrocarbon compounds, long chain hydrocarbon-based phosphates, long chain hydrocarbon-based sulfates, and combinations thereof.

It is recognized that the selection of the surface active compound should be made in view of the surface properties of the ink to be deposited in the sub-pixel well and of the black matrix surrounding the sub-pixel wells. For example, in order to increase the ink-phobicity of the outer surface of a black matrix relative to a selected ink, a surface active compound having a lower surface energy than the selected ink should be used. In order to reduce the ink-phobicity of the outer surface of a black matrix material relative to a selected ink, a surface active compound having a higher surface energy than the selected ink should be used. The surface energy of the ink may be between about 25 dynes/cm and about 35 dynes/cm. The ink surface energies described herein were measured using an EZ-Pi tensiometer, available from Kibron Inc. of Finland, according to the manufacturer's instructions. The tensiometer was initialized and calibrated with deionized water before the measurements were taken. The surface energies may also be measured using other apparatus, such as other commercially available tensiometers. The surface energies of two of the surface active compounds described herein, S-107B, a fluoroalkyl polyoxyethylene polymer from Chemguard, and a silicone oil are 21 dynes/cm and 21.5 dynes/cm respectively. As defined herein, the treatment-modified surface energy of the surface active compound-treated surface of the glass substrate and the black matrix is the surface energy of the surface active compound, which may be measured by an EZ-Pi tensiometer or other commercially available tensiometers. Preferably, the surface energy difference between the selected ink and the surface active compound-treated surface of the glass substrate and the black matrix is between about 4 dynes/cm and about 12 dynes/cm, such as between about 4 dynes/cm and about 10 dynes/cm, and is more preferably about 10+/−2 dynes/cm when the surface energies of the ink and the surface active compound are measured by an EZ-Pi tensiometer.

The surface active compound may be delivered to the glass substrate and black matrix in multiple ways. In one embodiment, the surface active compound is a solid or a liquid that is diluted in one or more volatile solvents before the glass substrate and black matrix are exposed to the surface active compound. The glass substrate and the black matrix may be exposed to a solution of the surface active compound dissolved in one or more volatile solvents by immersing the substrate in the solution, i.e., dip coating, or spraying the solution on the glass substrate, such as with a liquid dispenser or an atomizer. By using one or more volatile solvents such as acetone, methyl ethyl ketone, an ether, e.g., ethyl ether, or an alcohol, e.g., isopropanol, ethanol, methanol, or isobutanol, the glass substrate may be air dried and the one or more volatile solvents can be substantially removed from the liquid, by evaporation, resulting in the formation of a thin layer of the surface active compound on the glass substrate and black matrix that is substantially free of the one or more volatile solvents. A thin, uniform layer of the surface active compound may be obtained by using a highly diluted solution of the surface active compound. The glass substrate may also be dried using air drying equipment, such as an air knife or nitrogen gun.

The ratio of the surface active compound to the solvent may be between about 1:1 and about 1:100,000. In one embodiment, the ratio of the surface active compound to the solvent is about 1:1000. The ratio of the surface active compound to the solvent may be varied to optimize the spreading of the ink within the sub-pixel wells.

In another embodiment, the surface active compound is a solid or a liquid that is vaporized before the glass substrate and black matrix are exposed to the surface active compound. The black matrix and glass substrate may be exposed to the vaporized surface active compound by passing the substrate through a vapor phase of the surface active compound and a carrier gas, such as an inert gas or nitrogen, or a carrier gas mixture, such as air. A thin layer or coating of the surface active compound is deposited from the vaporized surface active compound onto the black matrix and glass substrate. Dilution with solvent is not required when the surface active compound is vaporized before the substrate is exposed to the surface active compound.

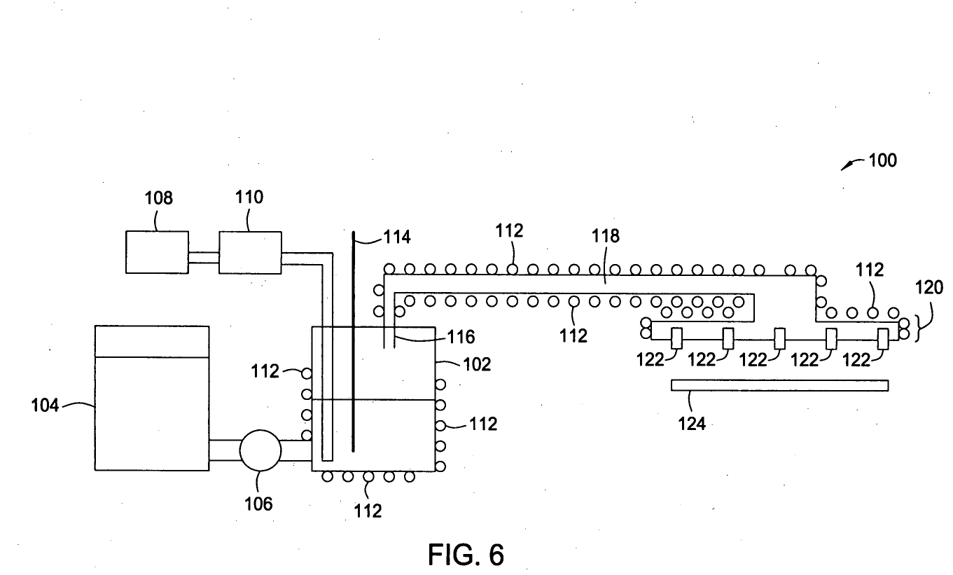

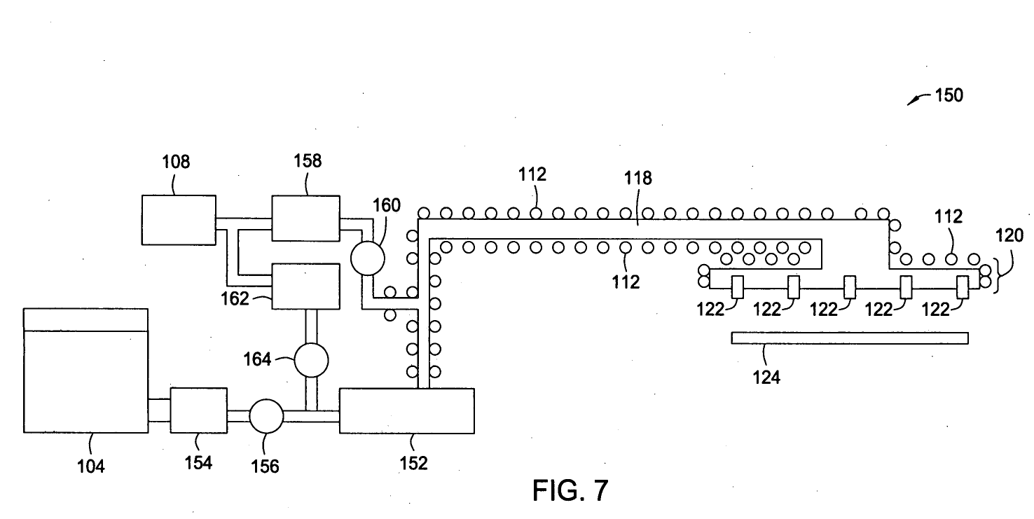

FIGS. 6 and 7 show examples of an apparatus that may be used to vaporize the surface active compound. Apparatus 100 shown in FIG. 6 includes a bubbler-type vaporizer 102 that is connected to a source 104 of the surface active compound. Flow of the surface active compound to the vaporizer 102 is regulated by a control valve 106 between the source 104 of the surface active compound and the vaporizer 102. A carrier gas such as nitrogen (N₂) is introduced into the vaporizer 102 from carrier gas source 108. The flow of the carrier gas is controlled by mass flow controller (MFC) 110 between the carrier gas source 108 and the vaporizer 102. Heating elements 112 disposed around the perimeter of the vaporizer 102 provide thermal energy to heat the vaporizer 102 to a temperature sufficient to vaporize the surface active compound. Optionally, an ultrasonic homogenizer 114 is disposed in the vaporizer to facilitate vaporization of the surface active compound. The vaporized surface active compound is removed from the vaporizer 102 at vaporizer outlet 116 and flowed through a line 118 that connects the vaporizer 102 and a heated applicator 120 that is a heated linear device having multiple outlets 122, e.g., nozzles or holes, through which the vaporized precursor is distributed to a substrate 124 beneath the heated applicator 120. Heating elements 112 on the heated applicator 120 and line 118 provide heat that helps prevent condensation of the vaporized surface active compound on parts of the apparatus. The substrate 124 may be moved horizontally with respect to the heated applicator 120 by a linear translation device (not shown) such that the entire surface of the substrate 124 is exposed to the vaporized surface active compound distributed by the heated applicator 120.

FIG. 7 shows an example of an apparatus 150 that includes a source 104 of a surface active compound and a heated applicator 120 that is connected by a heated line 118 to a vaporizer, as described above with respect to FIG. 6. Vaporizer 152 of apparatus 150 may be a commercially available vaporizer, such as a VoDM-A vaporizer available from MKS Instruments. The vaporizer 152 heats the surface active compound to a temperature sufficient to vaporize the surface active compound. The surface active compound is introduced into the vaporizer 152 from the source 104 of the surface active compound via a liquid flow meter (LFM) 154 and control valve 156 between the liquid flow meter (LFM) 154 and the vaporizer 152. A carrier gas, such as nitrogen may also be introduced into the vaporizer 152 from a carrier gas source 108 via MFC 162 and control valve 164. The carrier gas may also be introduced into the line 118 downstream of the vaporizer via MFC 158 and control valve 160. The vaporized precursor is distributed to substrate 124 beneath the heated applicator 120. Heating elements 112 on the heated applicator 120 and line 118 provide heat that helps prevent condensation of the vaporized surface active compound on the apparatus. The substrate may be moved horizontally with respect to the heated applicator by a linear translation device (not shown) such that the entire surface of the substrate is exposed to the vaporized surface active compound distributed by the heated applicator 120.

While FIGS. 6 and 7 show examples of equipment that may be used to expose the glass substrate and black matrix to a surface active compound, other equipment may be used. The equipment used to expose the glass substrate and black matrix to the surface active compound and dry the glass substrate may include one or more stand-alone pieces of equipment or one or more pieces of equipment that are integrated with other pieces of equipment that are used to process the substrate. For example, the equipment may be integrated with a system used to pattern the black matrix such that the glass substrate and the black matrix may be exposed to the surface active compound immediately after the last step of the formation of the black matrix, such as a rinsing step. Alternatively, the equipment may be integrated with an inkjet system used to deposit the ink in the sub-pixel wells such that the glass substrate and the black matrix are treated immediately before the inkjet deposition. The treatment may also be combined with other surface treatment steps, such as baking, before color filter deposition in the inkjet system.

It is believed that embodiments of the invention may be used to treat many or all of the commercially available black matrix materials, such as black matrix resins, which generally include one or more pigments, such as carbon black or an organic pigment, dispersed in a resin, such as an acrylic or polyimide resin, and chromium oxide-based black matrix materials that include a photoresist. It is also believed that embodiments of the invention may be used with many or all of the commercially available inks used for color filters. The inks may include components such as color pigments and dyes, solvents, additives, acrylic monomers, and acrylic and/or methacrylic oligomers.

Sub-pixel wells containing ink with a substantially uniform upper surface profile have been obtained using embodiments of the invention. By coating the surface of both the glass substrate at the bottom of a sub-pixel well and the black matrix surrounding the sub-pixel well with a layer deposited from the surface active compounds described herein, the surface energies of the black matrix and the glass substrate are made identical or very similar, and the spreading of the ink within the sub-pixel well is substantially unaffected by the composition of the black matrix prior to the treatment of the black matrix with the surface active compound. Further evidence that embodiments of the invention provide the coated black matrix and coated glass substrate with similar surface energies is provided by data collected from tests in which 30 picoliter drops of an ink were deposited on a glass substrate and a black matrix using a Spectra SE128 inkjet printhead. Immediately after the drops were deposited, the diameter of the deposited drops on the black matrix and glass substrate were measured using a Keyence VH digital microscope that has the capability to measure the radius of the deposited drop. It was found that a drop of one type of ink deposited on either a black matrix material or glass substrate resulted in the formation of drops with different diameters on the different materials, while a drop of the same type of ink deposited on either a black matrix material or glass substrate treated according to embodiments of the invention results in the formation of drops having substantially similar diameters. For example, it was found that the ratio of the drop radius of a drop of an ink on an untreated black matrix to the drop radius of a drop of the ink on an untreated glass substrate was about 1.17:1, while the ratio of the drop radius of the ink on a black matrix to the drop radius of the ink on a glass substrate was about 1:1 when the black matrix and glass substrate were treated with a solution containing a silicone oil dissolved in isopropanol at a ratio of 1:1000 according to embodiments of the invention before the ink drops were deposited on the glass substrate and the black matrix. The drop radii of a drop of ink on the treated glass substrate and a drop of ink on the treated black matrix were smaller than the drop radii of a drop of ink on the untreated glass substrate and the untreated black matrix respectively. Thus, the ink-philicity of the glass substrate and the ink-philicity of the black matrix were decreased by the treatment. Preferably, the drop radius of an ink drop on a treated glass substrate is about 6% to about 30% less than the drop radius of an ink drop on an untreated glass substrate, and the drop radius of an ink drop on a treated black matrix is about 6% to about 30% less than the drop radius of an ink drop on an untreated black matrix.

While it was found that embodiments of the invention provide a method of enhancing the formation of ink drops of some inks with a ratio of the drop radius of the ink on the black matrix to the drop radius of the ink on the glass substrate of about 1:1, it was also found that for other inks, glass substrates, and black matrices having different surface properties, the ratio of the drop radius of the ink on the black matrix to the drop radius of the ink on the glass substrate may be decreased from about 1:1 to about 0.8:1. For example, the ratio may be changed from about 1:1 to about 0.8:1 by increasing the ink-phobicity of the black matrix relative to the glass substrate.

Other embodiments of the invention provide a method of making a black matrix surface more ink-philic while making a glass substrate surface more ink-phobic by treating the black matrix and glass substrate with a surface active compound that has a surface energy that is higher than the surface energy of the black matrix and lower than the surface energy of the glass substrate. A ratio of the drop radius of an ink on a black matrix to the drop radius of the ink on a glass substrate changed from 0.56:1 to 0.8:1 when a glass substrate and a highly ink-phobic black matrix were treated with a surface active compound that had a surface energy higher than the surface energy of the black matrix and lower than the surface energy of the glass substrate.

Thus, embodiments of the invention provide methods of changing the ratio of the drop radius of an ink on a black matrix to the drop radius of the ink on a glass substrate from greater than about 1:1 or less than about 0.8:1 to between about 0.8:1 and about 1:1.

Embodiments of the invention described herein do not have the disadvantages of plasma-based black matrix treatment methods, such as argon plasma or fluorine-based plasma treatments, that have been developed to enhance a uniform distribution of ink within sub-pixel wells. For example, removal of some of the black matrix has been observed with argon plasma treatments and fluorine-based plasma treatments. Fluorine-based plasma treatments can also weaken the black matrix, etch the glass substrate, and generate toxic fluorine-containing waste. Plasma-based methods generally require special chambers that can be used to form a plasma or contain toxic waste.

Thus, embodiments of the invention provide a method of treating a glass substrate and a black matrix that enhances the quality of color filters manufactured by inkjet printing systems. By depositing a thin layer on the glass substrate and black matrix from the surface active compound, the black matrix may also be protected from undesirable reactions with the ink and is not physically damaged by the treatment process itself.

The following examples illustrate embodiments of the invention.

### EXAMPLE 1

Inkjet ink was deposited in a sub-pixel well of a black matrix (comprising PSK1000 from Brewer Science) on a glass substrate, and the upper surface profile of the ink was analyzed by an Alpha-Step 200 profilometer available from Tencor. The upper surface profile was highly concave-shaped, and deposited ink spread over the black matrix. An identical black matrix on a glass substrate was then treated with S-107B, a fluoroalkyl polyoxyethylene polymer from Chemguard, in isopropanol at a ratio of 1:1000 by dipping the substrate in the S-107B/isopropanol solution and completely dried by a filter nitrogen air gun. Ink was then deposited in a sub-pixel well of the black matrix, and the upper surface profile of the ink was analyzed. The upper surface profile was substantially less concave-shaped and substantially uniform over the entire sub-pixel well. Furthermore, the ink did not spread over the black matrix material.

### EXAMPLE 2

Inkjet ink was deposited in a sub-pixel well of a black matrix of high ink-phobicity, and the upper surface profile of the ink was analyzed by an Alpha-Step 200 profilometer available from Tencor. The upper surface profile was highly dome-shaped. An identical black matrix on a glass substrate was then treated with a silicone oil that is a polydimethylsiloxane chemical from Brookfield Engineering Laboratory Inc., in IPA (1:10 k) by dipping the substrate in the silicone oil/isopropanol solution and then completely dried by a filter nitrogen air gun. Ink was then deposited in a sub-pixel well of the black matrix, and the upper surface profile of the ink was analyzed. The upper surface profile was substantially less dome-shaped and substantially uniform over the entire sub-pixel well. Furthermore, the ink did not spread over the black matrix material.

While the foregoing is directed to embodiments of the present invention, other and further embodiments of the invention may be devised without departing from the basic scope thereof, and the scope thereof is determined by the claims that follow.

1. A method of treating a glass substrate and a black matrix thereon for a flat panel display, comprising:
exposing the glass substrate and the black matrix to a surface active compound under conditions sufficient to increase or decrease the ink-phobicity or ink-philicity of at least one member selected from the group consisting of the black matrix and an outer surface of the glass substrate that is not covered by the black matrix prior to delivery of an ink within sub-pixel wells of the black matrix.

2. The method of claim 1 wherein the black matrix comprises an outer surface, and the exposing the black matrix to the surface active compound increases or decreases the ink-phobicity of the outer surface of the black matrix.

3. The method of claim 1 wherein the exposing the glass substrate to the surface active compound increases or decreases the ink-phobicity of the outer surface of the glass substrate.

4. The method of claim 1 wherein the black matrix comprises an outer surface, and the exposing the black matrix to the surface active compound increases or decreases the ink-philicity of the outer surface of the black matrix.

5. The method of claim 1 wherein the exposing the glass substrate to the surface active compound increases or decreases the ink-philicity of the outer surface of the glass substrate.

6. The method of claim 1 wherein the surface active compound is selected from the group consisting of silane-based organic compounds, fluorinated hydrocarbons, long chain hydrocarbon-based acids, long chain hydrocarbon-based esters, long chain hydrocarbon-based phosphates, long chain hydrocarbon-based sulfates, and combinations thereof.

7. The method of claim 1 wherein the surface active compound is dissolved in one or more volatile solvents before the glass substrate and the black matrix are exposed to the surface active compound.

8. The method of claim 1 wherein the surface active compound is vaporized before the glass substrate and the black matrix are exposed to the surface active compound.

9. The method of claim 1 wherein a layer having a thickness of about a submonolayer to about 100 Å is deposited from the surface active compound on the black matrix and the glass substrate.

10. (canceled)

11. A method of treating a glass substrate and a black matrix thereon for a flat panel display, comprising:
exposing the glass substrate and the black matrix to a surface active compound under conditions sufficient to modify the surface energy of at least one member selected from the group consisting of the black matrix and an outer surface of the glass substrate that is not covered by the black matrix prior to delivery of an ink within sub-pixel wells of the black matrix, wherein the difference between the modified surface energy of the black matrix or glass substrate and the surface energy of the ink is between about 4 dynes/cm and about 12 dynes/cm.

12. The method of claim 11 wherein the black matrix comprises an outer surface, and modifying the surface energy comprises increasing or decreasing the ink-phobicity of the outer surface of the black matrix.

13. The method of claim 11 wherein modifying the surface energy comprises increasing or decreasing the ink-phobicity of the outer surface of the glass substrate.

14. The method of claim 11 wherein the black matrix comprises an outer surface, and modifying the surface energy of the black matrix comprises increasing or decreasing the ink-philicity of the outer surface of the black matrix.

15. The method of claim 11 wherein modifying the surface energy comprises increasing or decreasing the ink-philicity of the outer surface of the glass substrate.

16. The method of claim 11 wherein the difference between the modified surface energy of the black matrix or glass substrate and the surface energy of the ink is about 10+/−2 dynes/cm.

17. A method of treating a glass substrate and a black matrix thereon for a flat panel display, comprising:
exposing the glass substrate and the black matrix to a surface active compound under conditions sufficient to modify the surface energy of at least one member selected from the group consisting of the black matrix and an outer surface of the glass substrate that is not covered by the black matrix prior to delivery of an ink within sub-pixel wells of the black matrix, wherein the surface energy is modified such that the ratio of a drop radius of the ink on the black matrix to a drop radius of the ink on the glass substrate is changed from greater than about 1:1 or less than about 0.8:1 to between about 0.8:1 and about 1:1 after the exposure to a surface active compound.

18. The method of claim 17 wherein modifying the surface energy comprises decreasing the ink-philicity of both the black matrix and the glass substrate.

19. The method of claim 17 wherein modifying the surface energy comprises increasing the ink-phobicity of the black matrix relative to the glass substrate.

20. The method of claim 17 wherein the surface active compound has a higher surface energy than the surface energy of the black matrix prior to the exposure of the black matrix to the surface active compound, and the surface active compound has a lower surface energy than the surface energy of the glass substrate prior to the exposure of the glass substrate to the surface active compound.

21. The method of claim 20 wherein modifying the surface energy comprises increasing the ink-philicity of the black matrix and increasing the ink-phobicity of the glass substrate.

22. An apparatus for treating a glass substrate and a black matrix thereon for a flat panel display, comprising:
a vaporizer;
a source of a surface active compound connected to the vaporizer;
a heated applicator adapted to distribute a vaporized precursor comprising the surface active compound to a glass substrate and a black matrix thereon; and
a heated line connecting the vaporizer and the heated applicator.

23. The apparatus of claim 22 wherein the heated applicator comprises multiple nozzles.

24. The apparatus of claim 22 further comprising a homogenizer disposed in the vaporizer.

25. The apparatus of claim 22 further comprising a source of carrier gas connected to the heated line.

26. The method of claim 11 wherein the surface energy is modified such that the radius of a drop of the ink deposited on the exposed glass substrate is between about 6% and about 30% less than the radius of a drop of the ink deposited on the glass substrate prior to the exposure to a surface active compound, and the radius of a drop of the ink deposited on the exposed black matrix is between about 6% and about 30% less than the radius of a drop of the ink deposited on the black matrix prior to the exposure to a surface active compound.
